(19) United States
(12) Patent Application Publication
(10) Pub. No.: US 2016/0276503 A1
(43) Pub. Date: Sep. 22, 2016

(54) PHOTOVOLTAIC CELL AND MANUFACTURING METHOD OF PHOTOVOLTAIC CELL

(71) Applicant: Panasonic Intellectual Property Management Co., Ltd., Osaka (JP)

(72) Inventor: Masahiro KASANO, Osaka (JP)

(21) Appl. No.: 15/068,959

(22) Filed: Mar. 14, 2016

(30) Foreign Application Priority Data
Mar. 19, 2015 (JP) 2015-056718
Jan. 8, 2016 (JP) 2016-002209

(51) Int. Cl. H01L 31/0232; H01L 31/18; H01L 31/0735; H01L 31/054; H01L 31/049

(52) U.S. Cl. CPC H01L 31/02327; H01L 31/0543; H01L 31/049; H01L 31/0735; H01L 31/18

(57) ABSTRACT

A photovoltaic cell includes a translucent substrate; a photoelectric conversion element disposed on a light emission surface of the substrate; and a light guide member disposed on a light incidence surface of the substrate, at a position opposite the photoelectric conversion element across the substrate. A photovoltaic cell is manufactured by forming a first hydrophilic region on a light incidence surface of a translucent substrate, disposing a light guide member within the first hydrophilic region, forming a second hydrophilic region on a light emission surface of the substrate, and disposing a photoelectric conversion element in the second hydrophilic region.

### BACKGROUND

1. Technical Field

The present disclosure relates to a photovoltaic cell and a manufacturing method of a photovoltaic cell.

2. Description of Related Art

A concentrating photovoltaic cell in which a condenser lens and a photoelectric conversion element are integrally formed is disclosed in Japanese Patent No. 5120524 (hereinafter referred to as “Patent Literature 1”), for example.

The above concentrating photovoltaic cell includes a photoelectric conversion element and a condenser lens. The condenser lens transmits and focuses sunlight. The converged sunlight is emitted on the photoelectric conversion element. The photoelectric conversion element then converts optical energy of the emitted sunlight to generate power.

### SUMMARY

A photovoltaic cell according to the present disclosure includes a translucent substrate; a photoelectric conversion element disposed on a light emission surface of the substrate; and a light guide member disposed on a light incidence surface of the substrate, at a position opposite the photoelectric conversion element across the substrate.

A manufacturing method of a photovoltaic cell according to the present disclosure includes: forming a first hydrophilic region on a light incidence surface of a translucent substrate; disposing a light guide member within the first hydrophilic region; forming a second hydrophilic region on a light emission surface of the substrate; and disposing a photoelectric conversion element in the second hydrophilic region.

### BRIEF DESCRIPTION OF DRAWINGS

FIG. 1 is a sectional view illustrating a configuration of a photovoltaic cell according to an exemplary embodiment of the present disclosure;

FIG. 2 is a perspective view illustrating a substrate according to the exemplary embodiment;

FIG. 3 is a perspective view illustrating a light incidence surface side of the substrate according to the exemplary embodiment;

FIG. 4A is a sectional view for describing alignment of a condenser lens and the substrate according to the exemplary embodiment;

FIG. 4B is a sectional view for describing alignment of the condenser lens and the substrate according to the exemplary embodiment;

FIG. 4C is a sectional view for describing alignment of the condenser lens and the substrate according to the exemplary embodiment;

FIG. 5A is a sectional view illustrating a manufacturing method of the substrate according to the exemplary embodiment;

FIG. 5B is a sectional view illustrating the manufacturing method of the substrate according to the exemplary embodiment;

FIG. 5C is a sectional view illustrating the manufacturing method of the substrate according to the exemplary embodiment;

FIG. 5D is a sectional view illustrating the manufacturing method of the substrate according to the exemplary embodiment;

FIG. 5E is a sectional view illustrating the manufacturing method of the substrate according to the exemplary embodiment;

FIG. 6A is a sectional view illustrating the manufacturing method of the substrate according to the exemplary embodiment;

FIG. 6B is a sectional view illustrating the manufacturing method of the substrate according to the exemplary embodiment;

FIG. 6C is a sectional view illustrating the manufacturing method of the substrate according to the exemplary embodiment;

FIG. 6D is a sectional view illustrating the manufacturing method of the substrate according to the exemplary embodiment;

FIG. 6E is a sectional view illustrating the manufacturing method of the substrate according to the exemplary embodiment;

FIG. 7A is a perspective view illustrating a method for placing light guide members according to the exemplary embodiment;

FIG. 7B is a perspective view illustrating the method for placing light guide members according to the exemplary embodiment;

FIG. 8A is a perspective view illustrating the method for placing light guide members according to the exemplary embodiment;

FIG. 8B is a perspective view illustrating the method for placing light guide members according to the exemplary embodiment;

FIG. 9A is a sectional view illustrating a method for forming second hydrophilic regions on a light emission surface of the substrate according to the exemplary embodiment;

FIG. 9B is a sectional view illustrating the method for forming second hydrophilic regions on the light emission surface of the substrate according to the exemplary embodiment;

FIG. 9C is a sectional view illustrating the method for forming second hydrophilic regions on the light emission surface of the substrate according to the exemplary embodiment;

FIG. 9D is a sectional view illustrating the method for forming second hydrophilic regions on the light emission surface of the substrate according to the exemplary embodiment;

FIG. 9E is a sectional view illustrating the method for forming second hydrophilic regions on the light emission surface of the substrate according to the exemplary embodiment;

FIG. 10A is a sectional view illustrating the method for forming second hydrophilic regions on the light emission surface of the substrate according to the exemplary embodiment;

FIG. 10B is a sectional view illustrating the method for forming second hydrophilic regions on the light emission surface of the substrate according to the exemplary embodiment;

FIG. 10C is a sectional view illustrating the method for forming second hydrophilic regions on the light emission surface of the substrate according to the exemplary embodiment;

FIG. 10D is a sectional view illustrating the method for forming second hydrophilic regions on the light emission surface of the substrate according to the exemplary embodiment;

FIG. 10E is a sectional view illustrating the method for forming second hydrophilic regions on the light emission surface of the substrate according to the exemplary embodiment;

FIG. 11A is a perspective view illustrating a method for placing photoelectric conversion elements according to the exemplary embodiment;

FIG. 11B is a perspective view illustrating the method for placing photoelectric conversion elements according to the exemplary embodiment; and

FIG. 12 is a schematic sectional view of a photoelectric conversion element according to the exemplary embodiment.

### DETAILED DESCRIPTION

### Exemplary Embodiment

Hereinafter, an exemplary embodiment will be described in detail with reference to the accompanying drawings. It is noted, however, that descriptions in more detail than necessary will sometimes be omitted. For example, detailed descriptions of well-known items and duplicate descriptions of substantially the same configuration will sometimes be omitted. This is to avoid unnecessary redundancy in the following description and to facilitate understanding by those skilled in the art.

Note that the accompanying drawings and the following descriptions are provided so as to facilitate full understanding of the present disclosure by those skilled in the art, and these are not intended to limit the subject matter defined by the claims.

In the drawings, hatching may be omitted in some cases for facilitating understanding of the present disclosure.

### Exemplary Embodiment

### 1. Configuration of Photovoltaic Cell

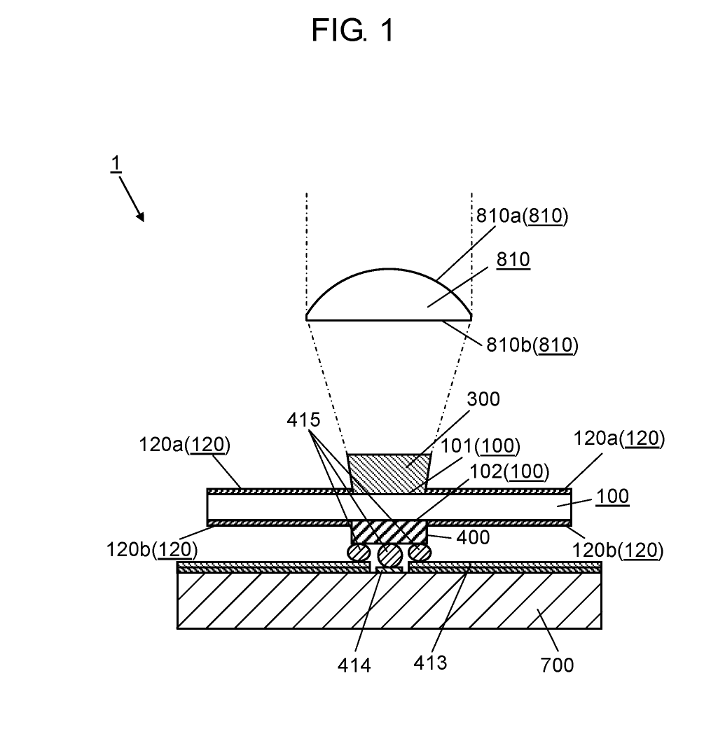

A configuration of a photovoltaic cell according to the present exemplary embodiment will be described below with reference to FIG. 1.

FIG. 1 is a schematic view illustrating a configuration of a photovoltaic cell according to the present exemplary embodiment.

As illustrated in FIG. 1, photovoltaic cell 1 includes substrate 100 having translucency such as a glass substrate, photoelectric conversion element 400, and light guide member 300. Photovoltaic cell 1 may also include condenser lens 810, circuit board 700, and the like.

Substrate 100 supports photoelectric conversion element 400 and light guide member 300. Later-described water-repellant region 120 is formed on a surface of substrate 100. Note that substrate 100 may be made of a material that can transmit sunlight, and it may be made of translucent materials other than glass.

Light guide member 300 is formed into a shape of an inverted truncated square pyramid, and constitutes an optical element which allows emission light from condenser lens 810 to be efficiently incident on photoelectric conversion element 400. Light guide member 300 includes a rod integrator or a microlens, or a combination thereof.

Condenser lens 810 and light guide member 300 are made of glass or resin, for example. Specifically, they are made of glass, or polymethylmethacrylate or polycarbonate with weather resistance, which is used for a photovoltaic power generation module. Condenser lens 810 and light guide member 300 may contain the above materials in a multilayer structure. Note that materials for condenser lens 810 and light guide member 300 are not particularly limited to the above materials, and any material can be used, so long as they have property of transmitting sunlight.

In addition, condenser lens 810, light guide member 300, and other members may contain an appropriate ultraviolet absorber in their constituent materials. With this, deterioration of each member due to ultraviolet rays can be prevented.

Further, an appropriate antireflection film may be formed on a surface of light guide member 300. With this, optical reflectivity of light guide member 300 in a sensitivity wavelength region of photoelectric conversion element 400 can be reduced. Examples of the antireflection film include an inorganic film of silicon oxide, silicon nitride, or magnesium fluoride, and a layered composite film of these materials.

In addition, an ultraviolet reflection film or an infrared reflection film may be formed on a surface of light guide member 300. With this, light having a wavelength out of the sensitivity wavelength region can be reflected on light guide member 300.

Condenser lens 810 condenses light, such as sunlight, incident on light incidence surface 810a, and emits this light to light guide member 300. The size of condenser lens 810 is appropriately determined according to the size of light guide member 300 to be used and focal length.

Photoelectric conversion element 400 converts incident light energy through light guide member 300 and substrate 100 to generate power. For example, a semiconductor material selected from Si, GaAs, InGaP, AlInGaAs, AlGaAs, InGaAs, InGaAsN, Ge, CuInGaSe, and CdTe or a combination thereof can be used for photoelectric conversion element 400. Specifically, photoelectric conversion element 400 can be configured as a high-power condenser by using inorganic materials such as a Group IV semiconductor, a Group III-V compound semiconductor, and a Group II-VI compound semiconductor. Further, photoelectric conversion element 400 can employ various types of structures such as a single-junction cell or multi-junction cell. In the present exemplary embodiment, the material of photoelectric conversion element 400 is GaAs as one example.

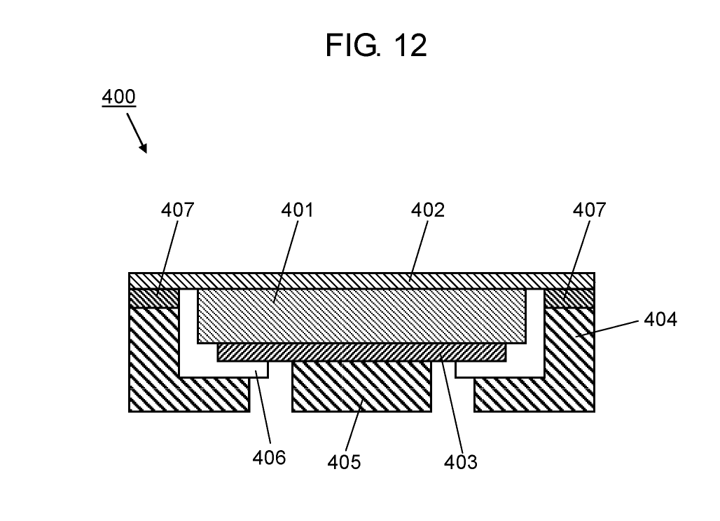

The structure of photoelectric conversion element 400 composing photovoltaic cell 1 according to the present exemplary embodiment will be described with reference to FIG. 12, while referring to FIG. 1.

FIG. 12 is a schematic sectional view of photoelectric conversion element 400 according to the present exemplary embodiment.

As illustrated in FIG. 12, photoelectric conversion element 400 includes power generation layer 401, first electrode 402, second electrode 403, first metal plating 404, second metal plating 405, insulating film 406, and connection electrode 407. In photoelectric conversion element 400, first electrode 402 and second electrode 403, which are connected to first metal plating 404 and second metal plating 405 respectively, are connected to first wiring 413 and second wiring 414 on circuit board 700 through conductive material 415 such as solder illustrated in FIG. 1. In this case, condenser lens 810 illustrated in FIG. 1 constitutes an optical element which allows sunlight to be efficiently incident on photoelectric conversion element 400. Power generation layer 401 is made of the above-mentioned semiconductor material.

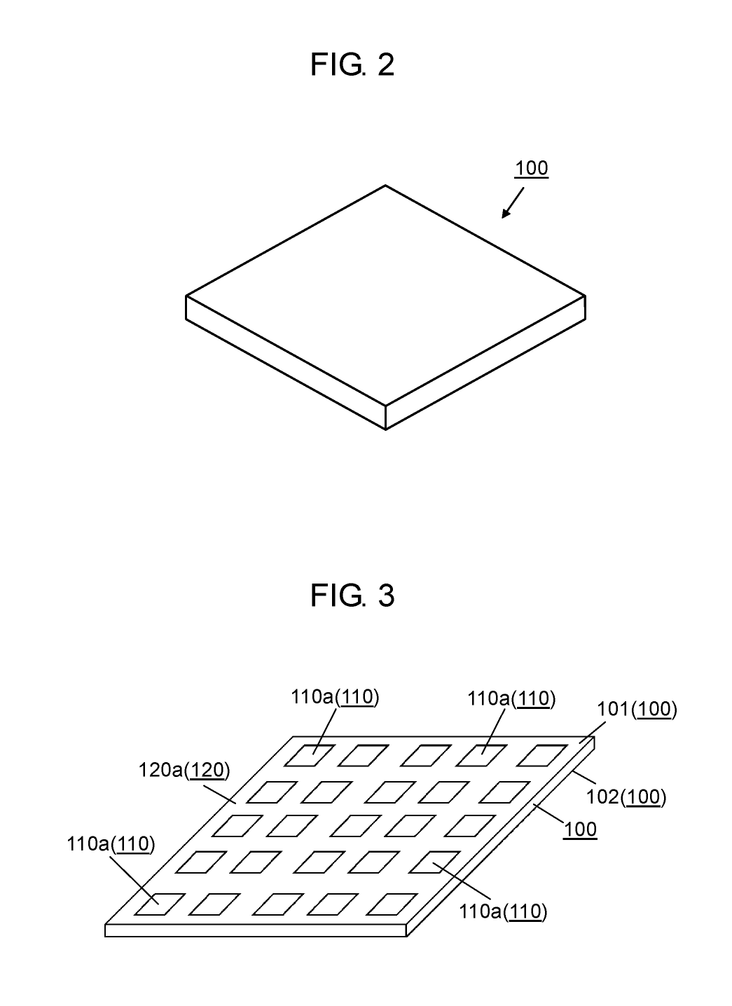

Substrate 100 of photovoltaic cell 1 according to the present exemplary embodiment will be described below with reference to FIGS. 2 and 3.

FIG. 2 is a perspective view illustrating a substrate according to the exemplary embodiment. FIG. 3 is a perspective view illustrating a light incidence surface side of the substrate according to the exemplary embodiment.

As illustrated in FIG. 3, substrate 100 includes first hydrophilic regions 110a and first water-repellant region 120a on light incidence surface 101 defining one surface. On the other hand, second hydrophilic regions 110b and second water-repellant region 120b are similarly formed on light emission surface 102 defining the other surface of substrate 100 illustrated in FIG. 1. First hydrophilic regions 110a and second hydrophilic regions 110b are enclosed by first water-repellant region 120a and second water-repellant region 120b respectively. When no distinction is made between first hydrophilic region 110a and second hydrophilic region 110b on substrate 100, they are merely described as “hydrophilic region 110”. Similarly, when no distinction is made between first water-repellant region 120a and second water-repellant region 120b, they are merely described as “water-repellant region 120”.

### 2. Manufacturing Method

A manufacturing method of the photovoltaic cell according to the present exemplary embodiment will be described in detail for each step.

[2-1. Alignment of Condenser Lens and Substrate]

<Step A>

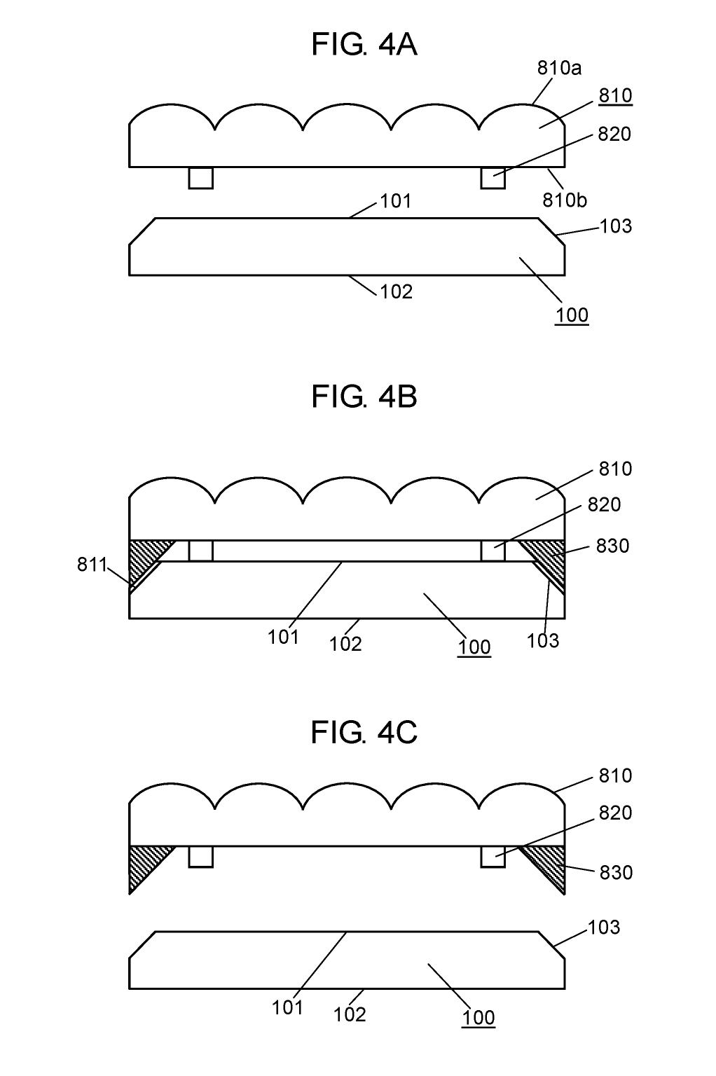

Firstly, alignment step A for determining relative positions of condenser lens 810 and substrate 100 will be described in step A1 and step A2 with reference to FIGS. 4A to 4C.

<Step A1>

As illustrated in FIG. 4A, condenser lens 810 and substrate 100 are provided. Condenser lens 810 has a convex surface on light incidence surface 810a side on which sunlight is incident. On the other hand, spacer 820 is provided on light emission surface 810b of condenser lens 810 for keeping a constant space with substrate 100.

Corners of light incidence surface 101 of substrate 100 facing light emission surface 810b of condenser lens 810 are beveled to form corner faces 103.

<Step A2>

Next, as illustrated in FIG. 4B, mold release agent 811 such as silicon emulsion is applied to corner faces 103 of substrate 100. Then, light emission surface 810b of condenser lens 810 and light incidence surface 101 of substrate 100 are disposed to be opposite to each other via spacer 820.

Next, epoxy putty 830, for example, is filled between condenser lens 810 and corner faces 103 of substrate 100 to which mold release agent 811 is applied. Filled epoxy putty 830 cures after a certain period of time.

Then, as illustrated in FIG. 4C, condenser lens 810 and substrate 100 are temporarily peeled. With epoxy putty 830, the relative positions of condenser lens 810 and substrate 100 are fixed. As a result, alignment of condenser lens 810 and substrate 100 is facilitated, and positional misalignment can be prevented in steps described later.

[2-2. Placement of Light Guide Member]

[2-2-1. Formation of First Hydrophilic Region and First Water-Repellant Region]

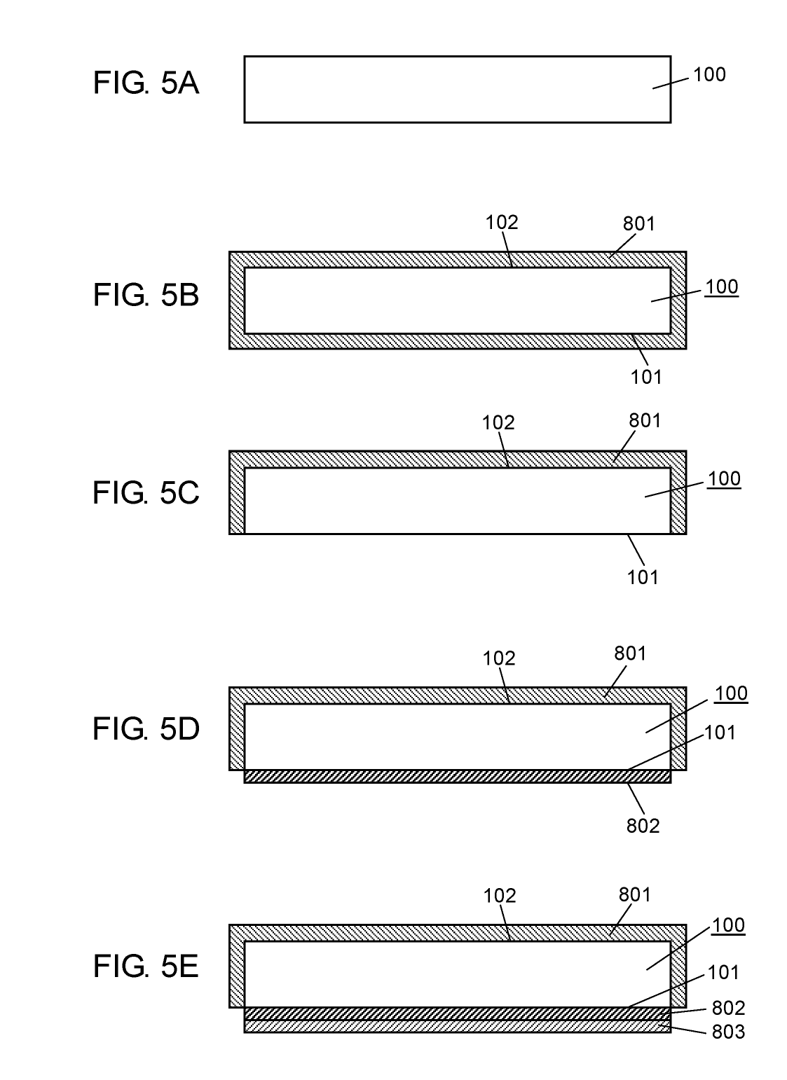

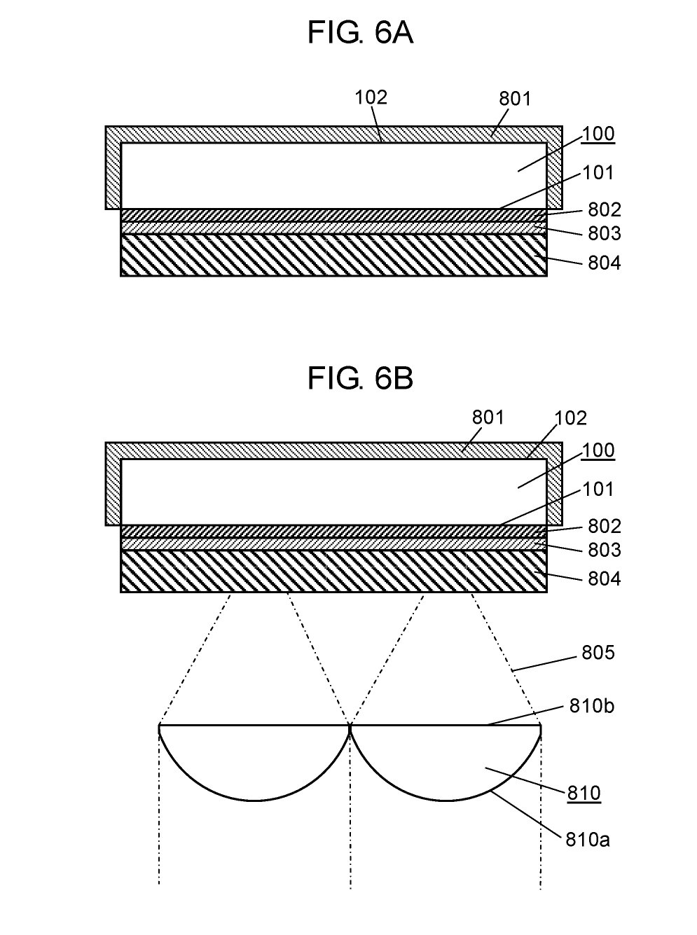

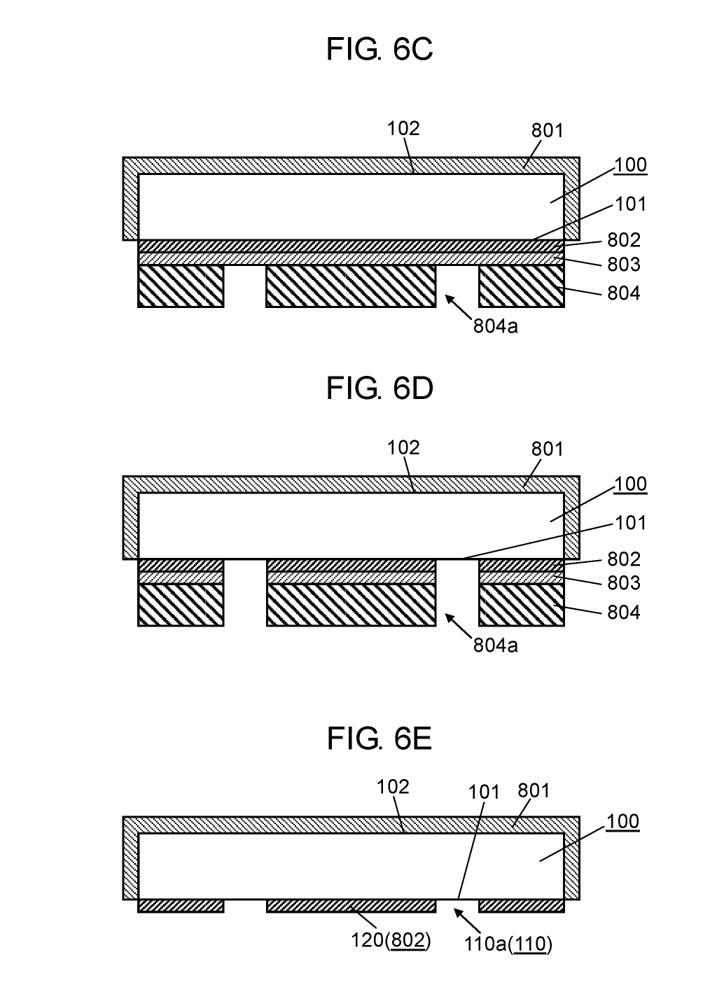

Steps B1 to B8 for forming first hydrophilic regions 110a and first water-repellant region 120a on light incidence surface 101 of substrate 100 will be described in detail with reference to FIGS. 5A to 6E.

FIGS. 5A to 6E illustrate a manufacturing method of the substrate according to the present exemplary embodiment.

Specifically, FIGS. 5A to 6E are sectional views illustrating steps B1 to B8 for forming first hydrophilic regions 110a and first water-repellant region 120a on light incidence surface 101 of substrate 100. With these steps, first hydrophilic regions 110a and first water-repellant region 120a enclosing first hydrophilic regions 110a are formed on light incidence surface 101 of substrate 100.

<Step B1>

As illustrated in FIG. 5A, substrate 100 having translucency, such as a glass substrate, is firstly provided.

Then, substrate 100 is immersed in a solution in which alkyl trichlorosilane or alkyl trialkoxysilane is dissolved. With this, the entire surface of substrate 100 is covered with an alkylsilane compound, and alkylsilane film 801 illustrated in FIG. 5B is formed. An example of alkyl trichlorosilane is octyl trichlorosilane. An example of alkyl trialkoxysilane is octyl trimethoxysilane or octyl triethoxysilane.

<Step B2>

Subsequently, alkylsilane film 801 covering light incidence surface 101 of substrate 100 is removed as illustrated in FIG. 5C. Alkylsilane film 801 is removed by a plasma process under an oxygen atmosphere. With this, one of the surfaces of substrate 100 is exposed as light incidence surface 101.

<Step B3>

Then, substrate 100 having exposed light incidence surface 101 is immersed in a solution in which fluoroalkyl trichlorosilane or fluoroalkyl trialkoxysilane is dissolved. An example of fluoroalkyl trichlorosilane is heptadecafluorooctyl ethyl trichlorosilane. An example of fluoroalkyl trialkoxysilane is heptadecafluorooctyl ethyl trimethoxysilane or heptadecafluorooctyl ethyl triethoxysilane. With these steps, light incidence surface 101 of substrate 100 is covered with fluoroalkylsilane film 802 as illustrated in FIG. 5D.

In this case, the surfaces, including light emission surface 102, other than light incidence surface 101 of substrate 100 are not covered with fluoroalkylsilane film 802. This is because surfaces such as light emission surface 102 of substrate 100 are covered with alkylsilane film 801 (see step B2). In other words, active hydrogen that can react with a fluoroalkylsilane compound is not present on substrate 100 covered with alkylsilane film 801, so that fluoroalkylsilane film 802 is not formed.

<Step B4>

Next, substrate 100 in the state illustrated in FIG. 5D is immersed in a solution in which an aminoalkylsilane compound is dissolved. With this, aminoalkylsilane film 803 having hydrophilicity is formed on fluoroalkylsilane film 802 on substrate 100. An example of aminoalkylsilane is aminopropyltriethoxysilane or aminopropyltrimethoxysilane. As a result, only light incidence surface 101 covered with fluoroalkylsilane film 802 becomes hydrophilic out of surfaces of substrate 100 as illustrated in FIG. 5E.

On the other hand, surfaces such as light emission surface 102 of substrate 100 covered with alkylsilane film 801 made of an alkylsilane compound are not hydrophilized. In other words, only light incidence surface 101 covered with fluoroalkylsilane film 802 is hydrophilized with fluoroalkylsilane film 802.

With the above process, aminoalkylsilane film 803 is further formed only on light incidence surface 101 of substrate 100. Specifically, a multilayer film of fluoroalkylsilane film 802 and aminoalkylsilane film 803 is formed on light incidence surface 101 of substrate 100. With this, fluoroalkylsilane film 802 is formed as sandwiched between substrate 100 and aminoalkylsilane film 803.

Aminoalkylsilane film 803 provides an effect of enabling uniform application of positive photoresist to light incidence surface 101 side of substrate 100 in step B5 described below. In addition, surfaces of substrate 100 such as light emission surface 102 side keep water-repellant property, because they are covered with alkylsilane film 801. Accordingly, an effect of inhibiting deposition of positive photoresist on the surfaces of substrate 100 such as light emission surface 102 is also provided.

<Step B5>

Next, as illustrated in FIG. 6A, positive photoresist such as a novolac resin is applied to aminoalkylsilane film 803 at a light incidence surface 101 side of substrate 100 to form photoresist layer 804.

<Step B6>

Then, condenser lens 810 is again disposed at the light incidence surface 101 side of substrate 100 as illustrated in FIG. 6B. Note that FIG. 6B schematically illustrates condenser lens 810 and substrate 100. Specifically, condenser lens 810 having spacer 820 is actually disposed with high precision by utilizing corner faces 103 of substrate 100 as illustrated in FIG. 4B.

Then, nearly parallel light 805 (including parallel light) in an ultraviolet wavelength region, for example, is made incident from a light incidence surface 810a side of condenser lens 810. Incident nearly parallel light 805 is converged on quadrilateral condenser lens 810, for example, in a plan view. Converged nearly parallel light 805 is emitted on positive photoresist layer 804. With this, positive photoresist layer 804 which covers the vicinity of the focal point of condenser lens 810 and formed on substrate 100 is exposed in a rectangular shape, for example.

Next, as illustrated in FIG. 6C, exposed positive photoresist layer 804 is removed to form opening 804a by immersion in a photoresist development solution containing an organic amine. With this, a plurality of rectangular regions corresponding to first hydrophilic regions 110a illustrated in FIG. 3 are formed on regions matching the vicinity of focal point of condenser lens 810.

<Step B7>

Next, as illustrated in FIG. 6D, aminoalkylsilane film 803 and fluoroalkylsilane film 802, which cover light incidence surface 101 of substrate 100, are removed within openings 804a formed by removing positive photoresist layer 804 in step B6. Specifically, aminoalkylsilane film 803 and fluoroalkylsilane film 802 are removed by a plasma process under an oxygen atmosphere. With this, light incidence surface 101 of substrate 100 is exposed in shapes of openings 804a of positive photoresist layer 804.

<Step B8>

Next, as illustrated in FIG. 6E, entire covering positive photoresist layer 804 is removed by using acetone or N-methylpyrrolidone. In addition, aminoalkylsilane film 803 layered on fluoroalkylsilane film 802 is removed by a plasma process under an oxygen atmosphere, for example.

By the processes in steps B1 to B8 described above, first hydrophilic regions 110a enclosed by fluoroalkylsilane film 802 are formed on the focal point or in the vicinity of the focal point of condenser lens 810. Fluoroalkylsilane film 802 functions as first water-repellant region 120a.

First hydrophilic regions 110a formed by the above exposure process will be described below in detail.

Firstly, wettability of first hydrophilic regions 110a with respect to an adhesive is higher than wettability of first water-repellant region 120a with respect to an adhesive.

In addition, the shape of each of first hydrophilic regions 110a is determined depending on the shape of light guide member 300 mounted on first hydrophilic region 110a. A rectangular shape has been described above as one example. However, the shape is not limited thereto. The shape of first hydrophilic regions 110a may be a polygon such as triangle, quadrilateral, or hexagon, or circle or ellipse, according to the shape of light guide member 300.

In addition, each first hydrophilic region 110a preferably has a shape same as the shape of the surface (specifically, the surface of light guide member 300 facing substrate 100 in the state in which light guide member 300 is mounted on substrate 100) of light guide member 300 to be mounted. Herein, “the same shape” means that the shape of each first hydrophilic region 110a and the surface of light guide member 300 to be mounted are in a congruence relation or a similarity relation in a mathematical concept.

Here, the surface area of the surface, which is adhered to substrate 100, of light guide member 300 mounted on substrate 100 is defined as S1. The area of one of first hydrophilic regions 110a is defined as S2. In this case, the value of S2/S1 is preferably from 0.64 to 1.44 both inclusive. When the value of S2/S1 is smaller than 0.64, an amount of an adhesive used to bond light guide member 300 to first hydrophilic region 110a is significantly small. Therefore, positional precision of light guide member 300 might be deteriorated. On the other hand, when the value of S2/S1 is larger than 1.44, an amount of an adhesive used to bond light guide member 300 to first hydrophilic region 110a is significantly large. Therefore, positional precision of light guide member 300 might also be deteriorated as in the above case.

The shape of each first hydrophilic region 110a is determined according to quadrilateral condenser lens 810, for example, in a plan view. It is to be noted that, when a light-shielding filter is provided between an exposure light source emitting nearly parallel light 805 and substrate 100, the shape is determined according to the shape of the light-shielding filter. In addition, the area of first hydrophilic regions 110a is determined by a distance between an exposure light source exposing positive photoresist layer 804 and substrate 100, and integrated exposure quantity of nearly parallel light 805.

The above condition may be different or same during formation of later-described second hydrophilic regions 110b on which photoelectric conversion elements 400 are disposed.

The case where positive photoresist layer 804 is exposed to form first hydrophilic regions 110a has been described above. However, it is not limited thereto. For example, first water-repellant region 120a enclosing a plurality of first hydrophilic regions 110a may be formed by an ink jet method, a screen printing method, a relief printing method, an intaglio printing method, or a microcontact printing method.

[2-2-2. Application of Adhesive]

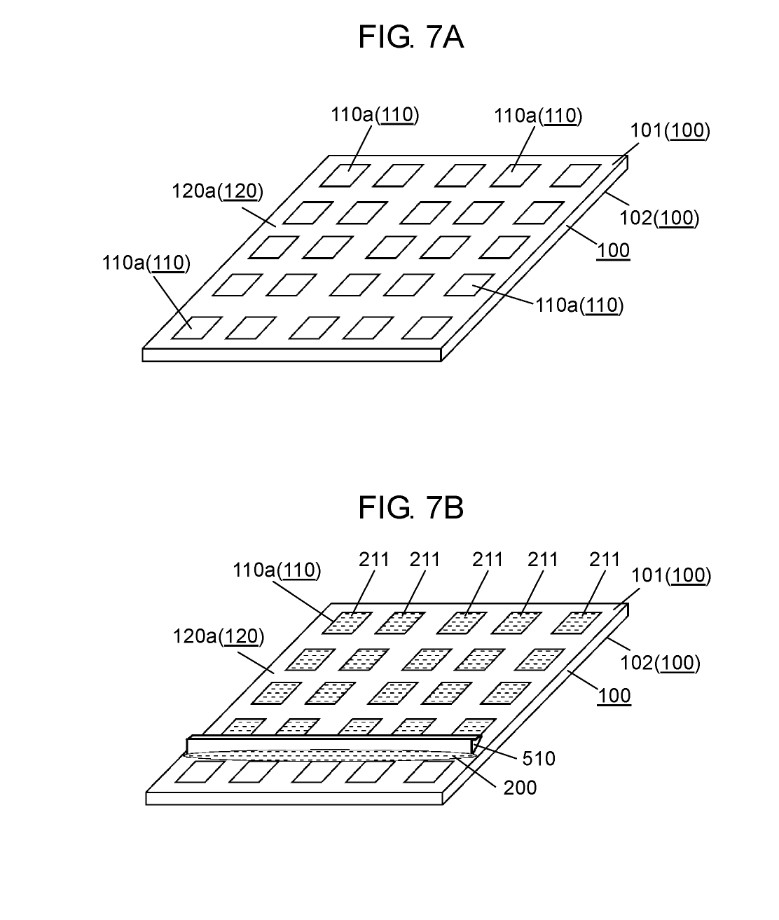

Next, step C for applying an adhesive to first hydrophilic regions 110a will be described with reference to FIGS. 7A and 7B.

<Step C>

FIGS. 7A and 7B are schematic perspective views for describing a method for applying an adhesive to the first hydrophilic regions on which light guide members are disposed according to the present exemplary embodiment. FIG. 7A illustrates substrate 100 having first water-repellant region 120a formed by a plurality of first hydrophilic regions 110a. FIG. 7B schematically illustrates a configuration and operation when adhesive 200 is applied to substrate 100.

Specifically, in step C, adhesive 200 for adhering light guide members 300 to substrate 100 is applied to first hydrophilic regions 110a on light incidence surface 101 of substrate 100.

Firstly, as illustrated in FIG. 7A, first water-repellant region 120a provided with a plurality of first hydrophilic regions 110a is formed on light incidence surface 101 side of substrate 100 by each step described above.

In this case, adhesive 200 is applied using squeegee 510, for example, as illustrated in FIG. 7B.

Specifically, hydrophilic adhesive 200 containing water as a main component is applied to light incidence surface 101 side of substrate 100, for example. Applied adhesive 200 is disposed in first hydrophilic regions 110a with the movement of squeegee 510. Adhesive 211 illustrated in FIG. 7B indicates adhesive 200 which is disposed in first hydrophilic regions 110a.

In this case, first water-repellant region 120a is formed to enclose first hydrophilic regions 110a. Therefore, hydrophilic adhesive 200 disposed in first hydrophilic regions 110a does not stick out onto first water-repellant region 120a.

In step C illustrated in FIG. 7B, squeegee 510 moves, while substrate 100 does not move. However, the configuration is not limited thereto. For example, a configuration is possible in which squeegee 510 does not move, while substrate 100 moves. Alternatively, both of squeegee 510 and substrate 100 may relatively move. In the present specification, the above configurations are collectively referred to as “relative movement”. Specifically, the wording of “a squeegee relatively moves on the substrate” includes three aspects (A) to (C), that is, the aspect (A) in which squeegee 510 moves but substrate 100 does not move, the aspect (B) in which squeegee 510 does not move but substrate 100 moves, and the aspect (C) in which both squeegee 510 and substrate 100 move.

In step C, after adhesive 200 is applied to one end of substrate 100, substrate 100 is tilted to raise the one end. Adhesive 200 flowing downward along the tilt may be sequentially poured into first hydrophilic regions 110a. In this case, squeegee 510 does not have to be particularly used.

Instead of the relative movement of squeegee 510 and substrate 100, an adhesive may be individually applied to each of first hydrophilic regions 110a using a dispenser.

[2-2-3. Mounting of Light Guide Member]

<Step D>

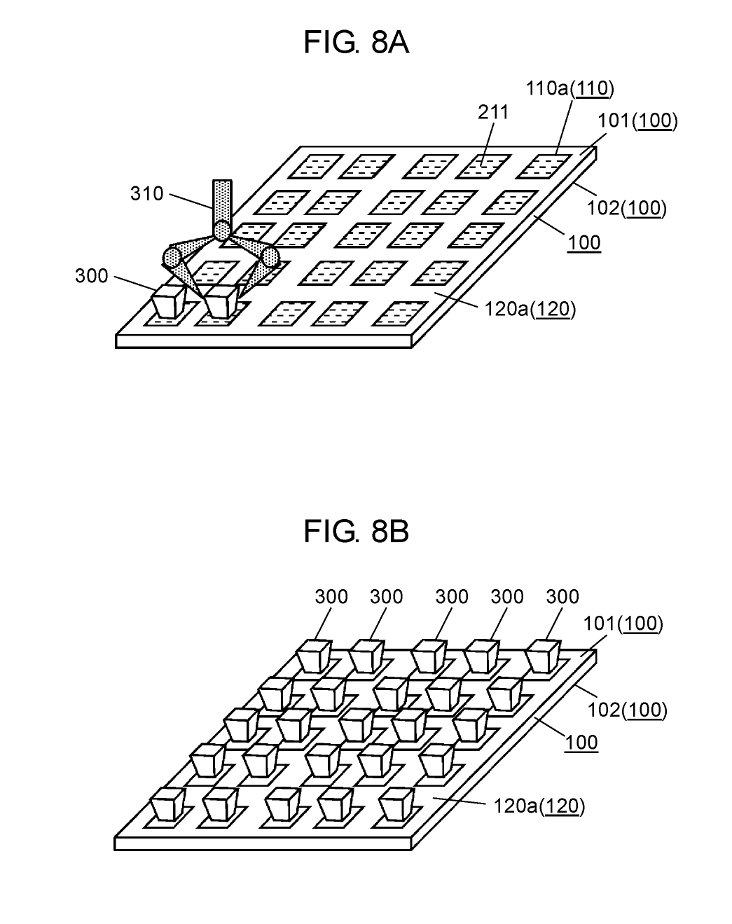

Next, step D for mounting light guide members 300 will be described with reference to FIG. 8A.

FIG. 8A is a perspective view schematically illustrating step D that is a method for placing the light guide members according to the present exemplary embodiment.

As illustrated in FIG. 8A, light guide member 300 with a shape of inverted truncated square pyramid is mounted on adhesive 211 applied to each of a plurality of first hydrophilic regions 110a using a mounting device 310, for example. Note that a known FA (Factory Automation) device can be used for mounting device 310.

In this case, interface tension (surface tension) of adhesive 211 is exerted on light guide member 300 which is mounted. With this, light guide member 300 moves to the center of adhesive 211 applied to each of first hydrophilic regions 110a. As a result, light guide member 300 is disposed at the center of each of first hydrophilic regions 110a by a self-alignment effect due to adhesive 211.

[2-2-4. Fixation of Light Guide Member]

<Step E>

Next, step E for fixing light guide members 300 will be described with reference to FIG. 8B.

As illustrated in FIG. 8B, light guide members 300 mounted on substrate 100 with adhesive 211 interposed therebetween are fixed in first hydrophilic regions 110a due to curing of adhesive 211. Adhesive 211 is cured by an appropriate curing method selected from known curing methods including ultraviolet curing, thermal curing, and natural curing.

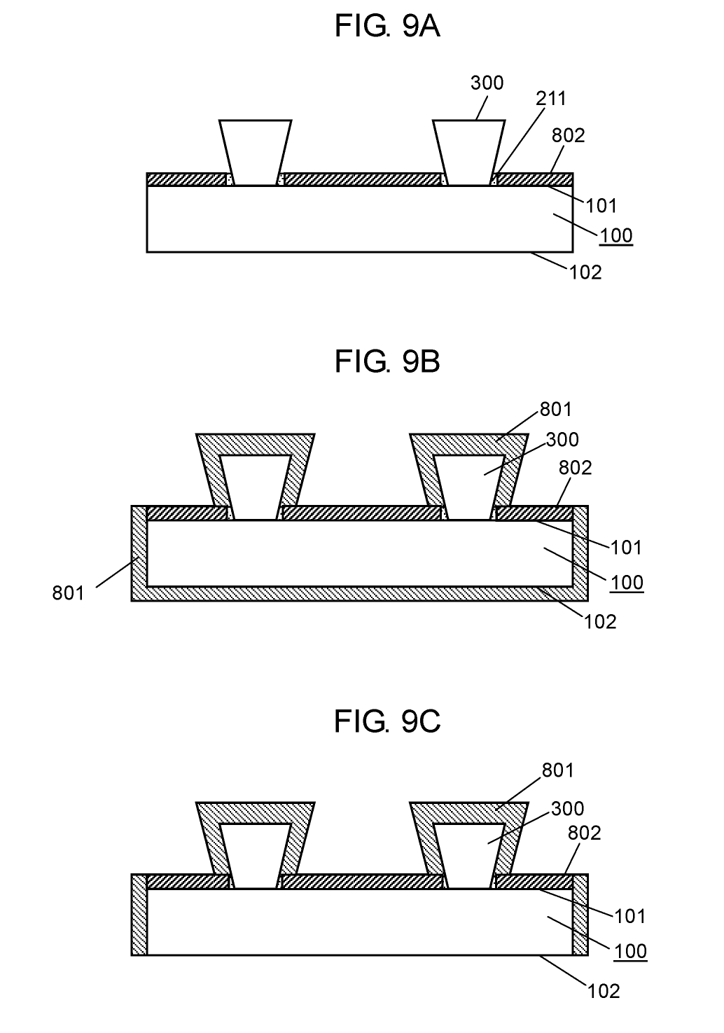

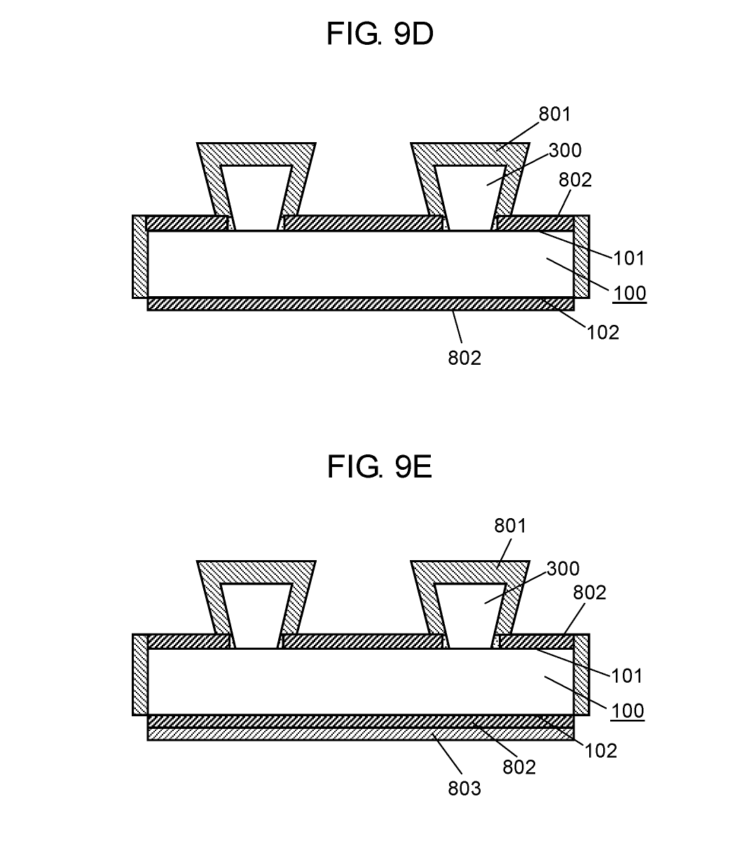

By each step described above, light guide members 300 can precisely be disposed in first hydrophilic regions 110a formed on the focal point or in the vicinity of the focal point of condenser lens 810 (see FIG. 9A).

[2-3. Placement of Photoelectric Conversion Element]

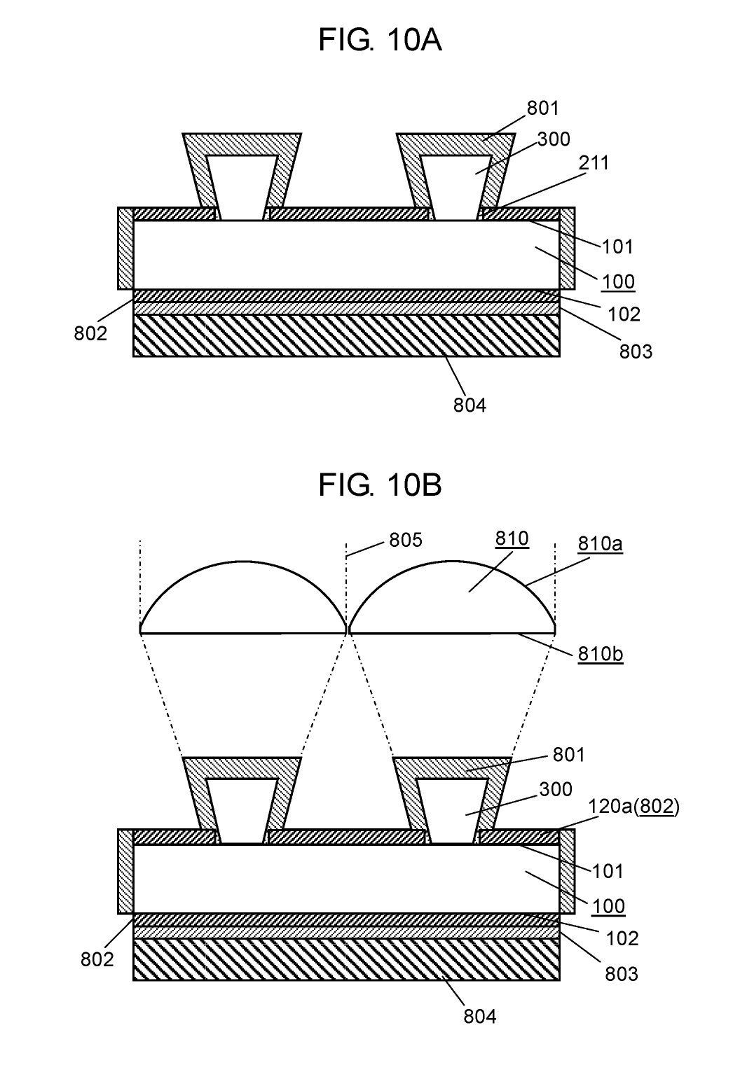

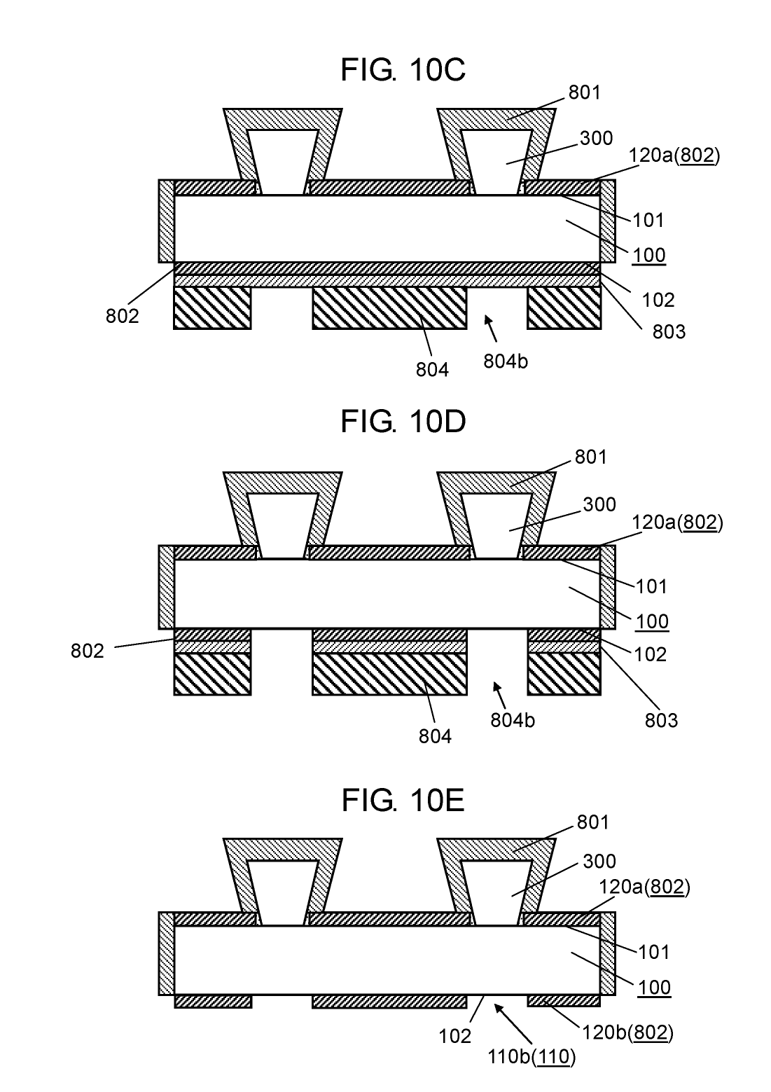

Next, a step for placing photoelectric conversion elements 400 on light emission surface 102 side of substrate 100 to which light guide members 300 are adhered will be described with reference to FIGS. 9A to 10E.

FIGS. 9A to 10E are sectional views illustrating a method for forming second hydrophilic regions on the light emission surface of the substrate according to the present exemplary embodiment.

[2-3-1. Formation of Second Hydrophilic Region and Second Water-Repellant Region]

<Step F1>

As illustrated in FIG. 9A, substrate 100 to which light guide members 300 are adhered by each of the above steps is provided.

Then, substrate 100 in the above state is immersed in a solution in which alkyl trichlorosilane or alkyl trialkoxysilane is dissolved. With this, alkylsilane film 801 is formed on the entire surface of substrate 100 other than the portion covered with fluoroalkylsilane film 802 having water-repellant property as illustrated in FIG. 9B. An example of alkyl trichlorosilane is octyl trichlorosilane. An example of alkyl trialkoxysilane is octyl trimethoxysilane or octyl triethoxysilane.

<Step F2>

Subsequently, alkylsilane film 801 covering light emission surface 102 of substrate 100 is removed as illustrated in FIG. 9C. Alkylsilane film 801 is removed by a plasma process under an oxygen atmosphere. With this, light emission surface 102 of substrate 100 is exposed.

<Step F3>

Then, substrate 100 having exposed light emission surface 102 is immersed in a solution in which fluoroalkyl trichlorosilane or fluoroalkyl trialkoxysilane is dissolved. An example of fluoroalkyl trichlorosilane is heptadecafluorooctyl ethyl trichlorosilane. An example of fluoroalkyl trialkoxysilane is heptadecafluorooctyl ethyl trimethoxysilane or heptadecafluorooctyl ethyl triethoxysilane. With these steps, light emission surface 102 of substrate 100 is covered with fluoroalkylsilane film 802 as illustrated in FIG. 9D.

In this case, the surfaces, including light incidence surface 101, other than light emission surface 102 of substrate 100 are not covered with fluoroalkylsilane film 802. This is because surfaces such as light incidence surface 101 of substrate 100 are covered with alkylsilane film 801 (see step F2). In other words, active hydrogen that can react with a fluoroalkylsilane compound is not present on substrate 100 covered with alkylsilane film 801, so that fluoroalkylsilane film 802 is not formed.

<Step F4>

Next, substrate 100 in the state illustrated in FIG. 9D is immersed in a solution in which an aminoalkylsilane compound is dissolved to form aminoalkylsilane film 803. An example of aminoalkylsilane is aminopropyltriethoxysilane or aminopropyltrimethoxysilane. As a result, only light emission surface 102 of substrate 100 covered with fluoroalkylsilane film 802 becomes hydrophilic as illustrated in FIG. 9E.

On the other hand, surfaces such as light incidence surface 101 of substrate 100 covered with alkylsilane film 801 made of an alkylsilane compound are not hydrophilized. In other words, only light emission surface 102 covered with fluoroalkylsilane film 802 is hydrophilized with fluoroalkylsilane film 802.

With this, aminoalkylsilane film 803 provides an effect of enabling uniform application of positive photoresist to light emission surface 102 side of substrate 100 in step F5 described below. In addition, surfaces of substrate 100 such as light incidence surface 101 side keep water-repellant property, because they are covered with alkylsilane film 801. Accordingly, an effect of inhibiting deposition of positive photoresist on the surfaces of substrate 100 such as light incidence surface 101 side is also provided.

<Step F5>

Next, as illustrated in FIG. 10A, positive photoresist such as a novolac resin is applied to aminoalkylsilane film 803 at a light emission surface 102 side of substrate 100 to form photoresist layer 804.

<Step F6>

Then, condenser lens 810 is again disposed at the light incidence surface 101 side of substrate 100 as illustrated in FIG. 10B. Note that FIG. 10B schematically illustrates condenser lens 810 and substrate 100. Specifically, condenser lens 810 having spacer 820 is actually disposed with high precision by utilizing corner faces 103 of substrate 100 as illustrated in FIG. 4B.

Then, nearly parallel light 805 (including parallel light) in an ultraviolet wavelength region, for example, is made incident from a light incidence surface 810a side of condenser lens 810. Incident nearly parallel light 805 is converged by condenser lens 810. Converged nearly parallel light 805 passes through light guide members 300 while being refracted, and is emitted from the surfaces of light guide members 300 facing light incidence surface 101 of substrate 100. The emitted light passes through substrate 100, and emitted on positive photoresist layer 804 at a light emission surface 102 side of substrate 100. With this, positive photoresist layer 804 which covers a condensing spot where light is condensed through condenser lens 810 and light guide members 300 or the vicinity of the condensing spot is exposed in a rectangular shape, for example.

Next, as illustrated in FIG. 10C, exposed positive photoresist layer 804 is removed to form openings 804b by immersion in a photoresist development solution containing an organic amine. With this, a plurality of rectangular regions corresponding to second hydrophilic regions 110b illustrated in FIG. 1 are formed on a region matching the condensing spot formed by condenser lens 810 and light guide members 300 or the vicinity of the condensing spot. In this case, the positional relation among condenser lens 810, light guide members 300, and substrate 100 is desirably the same as that of photovoltaic cell 1 illustrated in FIG. 1.

<Step (F7)>

Next, as illustrated in FIG. 10D, aminoalkylsilane film 803 and fluoroalkylsilane film 802, which cover light emission surface 102 of substrate 100, are removed within openings 804b formed by removing positive photoresist layer 804 in step F6. Specifically, aminoalkylsilane film 803 and fluoroalkylsilane film 802 are removed by a plasma process under an oxygen atmosphere. With this, light emission surface 102 of substrate 100 is exposed in shapes of openings 804b of positive photoresist layer 804.

<Step F8>

Next, as illustrated in FIG. 10E, entire covering positive photoresist layer 804 is removed by using acetone or N-methylpyrrolidone. In addition, aminoalkylsilane film 803 layered on fluoroalkylsilane film 802 is removed by a plasma process under an oxygen atmosphere, for example.

By the processes in steps F1 to F8 described above, second hydrophilic regions 110b enclosed by fluoroalkylsilane film 802 are formed on the condensing spot of condenser lens 810 through light guide members 300 or in the vicinity of the condensing spot. Fluoroalkylsilane film 802 functions as second water-repellant region 120b.

In this case, the area of second hydrophilic regions 110b which are formed in step F and on which photoelectric conversion elements 400 are mounted is larger than the area of the first hydrophilic regions 110a which are formed in step B and on which light guide members 300 are mounted. The reason for this is as follows. Firstly, a second distance from photoresist layer 804 to condenser lens 810 during formation of second hydrophilic regions 110b is different from a first distance from photoresist layer 804 to condenser lens 810 during formation of first hydrophilic regions 110a. Specifically, the exposure process of positive photoresist in step F is performed by light after passing through substrate 100. Therefore, the second distance from photoresist layer 804 to condenser lens 810 is increased. With this, light incident on light incidence surface 101 of substrate 100 spreads when passing through substrate 100. Consequently, the area of second hydrophilic regions 110b is larger than the area of first hydrophilic regions 110a.

[2-3-2. Application of Adhesive]

<Step G>

Next, in step G, adhesive 211 is applied to and filled in second hydrophilic regions 110b as in step C described with reference to FIGS. 7A and 7B. Note that the detailed description will be omitted, since it is similar to step C.

[2-3-3. Mounting of Photoelectric Conversion Element]

<Step H>

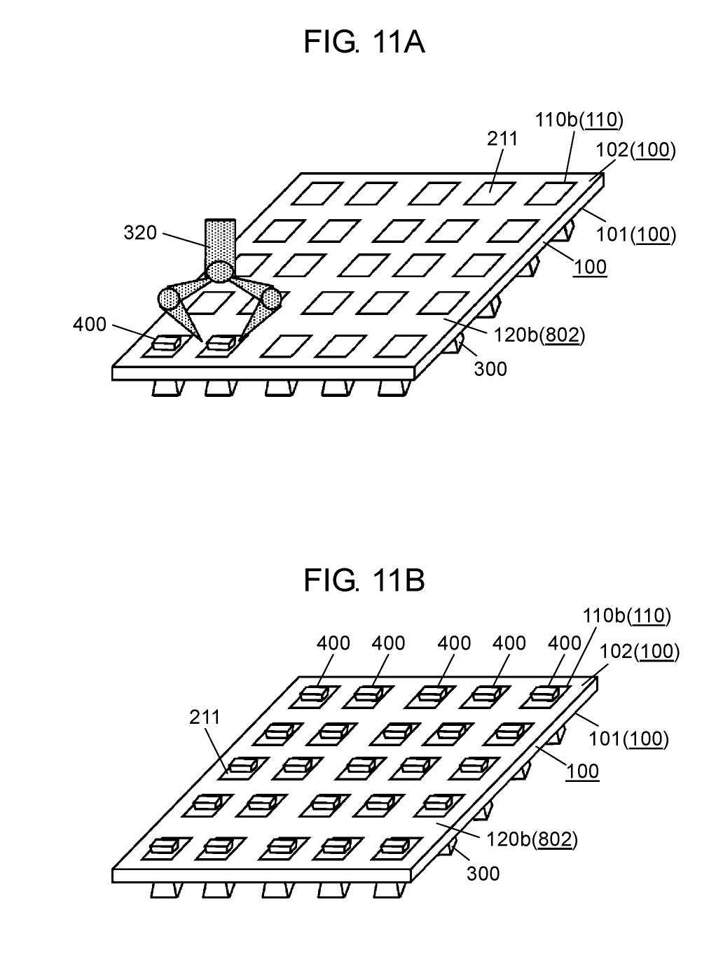

Next, a method for mounting photoelectric conversion elements 400 will be described with reference to FIG. 11A.

FIG. 11A is a perspective view schematically illustrating step H that is a method for placing the photoelectric conversion elements according to the present exemplary embodiment.

As illustrated in FIG. 11A, photoelectric conversion element 400 is mounted on adhesive 211 applied to each of a plurality of second hydrophilic regions 110b using mounting device 320, for example.

In this case, interface tension (surface tension) of adhesive 211 is exerted on photoelectric conversion element 400 which is mounted. With this, photoelectric conversion element 400 moves to the center of adhesive 211 applied to each of second hydrophilic regions 110b. As a result, photoelectric conversion element 400 is disposed at the center of each of second hydrophilic regions 110b by a self-alignment effect due to adhesive 211.

[2-3-4. Fixation of Photoelectric Conversion Element]

<Step I>

Finally, step I for fixing a photoelectric conversion element will be described with reference to FIG. 11B.

As illustrated in FIG. 11B, photoelectric conversion elements 400 mounted on substrate 100 with adhesive 211 interposed therebetween are fixed in second hydrophilic regions 110b due to curing of adhesive 211, as in step E.

### 3. Effect

Photovoltaic cell 1 according to the above exemplary embodiment includes translucent substrate 100; photoelectric conversion element 400 disposed on light emission surface 102 of substrate 100; and light guide member 300 disposed on a light incidence surface of substrate 100, at a position opposite photoelectric conversion element 400 across substrate 100. With this configuration, photovoltaic cell 1 is capable of efficiently guiding incident sunlight to photoelectric conversion element 400, whereby light use efficiency can be enhanced.

By each step described above, photoelectric conversion element 400 can precisely be disposed on a condensing spot formed by condenser lens 810 and light guide member 300 or the vicinity of the condensing spot (see FIG. 1).

A manufacturing method of photovoltaic cell 1 according to the present disclosure includes: forming first hydrophilic region 110a on light incidence surface 101 of translucent substrate 100; disposing light guide member 300 within first hydrophilic region 110a; forming second hydrophilic region 110b on light emission surface 102 of substrate 100; and disposing photoelectric conversion element 400 in second hydrophilic region 110b. Second hydrophilic region 110b which is formed on light emission surface 102 of substrate 100 and on which photoelectric conversion element 400 is disposed is formed by an exposure process of positive photoresist layer 804 using light guide member 300. Therefore, relative alignment between condenser lens 810 and both light guide member 300 and photoelectric conversion element 400 can easily and precisely be performed. This can allow sunlight incident on light guide member 300 to be reliably incident on photoelectric conversion element 400. Consequently, light use efficiency can be enhanced, whereby a highly efficient photovoltaic cell can be implemented.

### Other Exemplary Embodiments

As presented above, the exemplary embodiment has been described as an example of the technique described in the present application. However, the technique in the present disclosure is not limited to these, and can be applied to embodiments in which various changes, replacements, additions, omissions, or the like are made. Moreover, constituent elements described in the above exemplary embodiment can be combined to provide a new embodiment.

Other exemplary embodiments will be illustrated below.

The present exemplary embodiment describes that light incidence surface 101 and light emission surface 102 of substrate 100 undergo the exposure process, one at a time, to form corresponding hydrophilic regions 110 and water-repellant regions 120. However, the configuration is not limited thereto. For example, light incidence surface 101 and light emission surface 102 of substrate 100 may simultaneously undergo the exposure process to form corresponding hydrophilic regions 110 and water-repellant regions 120. In this case, positive photoresist is applied to both surfaces of substrate 100 to form photoresist layer 804, and then, both surfaces are exposed by incidence of nearly parallel light 805 on both surfaces.

In addition, the present exemplary embodiment may be configured such that photovoltaic cell 1 is provided with a tracking device which detects the direction of the sun and allows sunlight to be vertically incident on an optical axis of condenser lens 810 according to the direction of the sun. With this configuration, a more efficient photovoltaic cell can be implemented.

Note that the above-described embodiments have been described to exemplify the technique according to the present disclosure, and therefore, various modifications, replacements, additions, and omissions may be made within the scope of the claims and the scope of the equivalents thereof.

What is claimed is:

1. A photovoltaic cell comprising:
a translucent substrate;
a photoelectric conversion element disposed on a light emission surface of the substrate; and
a light guide member disposed on a light incidence surface of the substrate, at a position opposite the photoelectric conversion element across the substrate.

2. The photovoltaic cell according to claim 1, further comprising:
a condenser lens,
wherein the condenser lens is disposed at a position opposite the photoelectric conversion element across the substrate and the light guide member.

3. The photovoltaic cell according to claim 1,
wherein a water-repellant material is provided to enclose the photoelectric conversion element and the light guide member on the light emission surface and the light incidence surface of the substrate.

4. The photovoltaic cell according to claim 3,
wherein the light incidence surface of the substrate includes a first hydrophilic region which is enclosed by the water-repellant material and on which the light guide member is disposed,
the light emission surface of the substrate includes a second hydrophilic region which is enclosed by the water-repellant material and on which the photoelectric conversion element is disposed, and
an area of the second hydrophilic region is larger than an area of the first hydrophilic region.

5. The photovoltaic cell according to claim 4, wherein the first hydrophilic region and the second hydrophilic region have a rectangular shape.

6. A manufacturing method of a photovoltaic cell, the method comprising:
forming a first hydrophilic region on a light incidence surface of a translucent substrate;
disposing a light guide member within the first hydrophilic region;
forming a second hydrophilic region on a light emission surface of the substrate, at a position opposite the light guide member across the substrate; and
disposing a photoelectric conversion element in the second hydrophilic region.

7. The manufacturing method of a photovoltaic cell according to claim 6, wherein the first hydrophilic region and the second hydrophilic region are formed by an exposure process.

8. The manufacturing method of a photovoltaic cell according to claim 7, further comprising:
disposing a condenser lens on an optical axis passing through the light guide member and the photoelectric conversion element on a light incidence surface of the substrate.

9. The manufacturing method of a photovoltaic cell according to claim 8, wherein the exposure process for the second hydrophilic region is performed using light after passing through the condenser lens.

10. The manufacturing method of a photovoltaic cell according to claim 7, wherein the second hydrophilic region is formed by exposure to light passing through the light guide member, after the light guide member is disposed.

11. The manufacturing method of a photovoltaic cell according to claim 8, further comprising:
performing an exposure process for forming the first hydrophilic region after a photoresist layer is formed at a light incidence surface side of the substrate, and performing an exposure process for forming the second hydrophilic region after a photoresist layer is formed at a light emission surface side of the substrate,
wherein a first distance from the photoresist layer to the condenser lens during the exposure process for forming the first hydrophilic region is different from a second distance from the photoresist layer to the condenser lens during the exposure process for forming the second hydrophilic region.

12. The manufacturing method of a photovoltaic cell according to claim 11, wherein the second distance is longer than the first distance.
